(19) United States
(12) Patent Application Publication
(10) Pub. No.: US 2026/0134160 A1
(43) Pub. Date: May 14, 2026

(54) METHOD FOR ANALYZING SEISMIC VULNERABILITY OF URBAN BUILDING GROUP BASED ON POISSON BINOMIAL DISTRIBUTION

(71) Applicant: Southeast University, Jiangsu (CN)

(72) Inventors: Decheng FENG, Jiangsu (CN); Jiayi DING, Jiangsu (CN); Xuyang CAO, Jiangsu (CN)

(73) Assignee: Southeast University, Jiangsu (CN)

(21) Appl. No.: 19/178,872

(22) Filed: Apr. 15, 2025

(30) Foreign Application Priority Data
Sep. 13, 2024 (CN) 202411282024.0

(51) Int. Cl. G06F 30/13; G06F 30/27

(52) U.S. Cl. CPC G06F 30/13; G06F 30/27

(57) ABSTRACT

A method for analyzing the seismic vulnerability of an urban building group based on Poisson binomial distribution includes these steps: (1) establishing a simplified numerical model of the building group; (2) selecting seismic motion records consistent with site features; (3) acquiring a structural and non-structural damage database for the building group; (4) creating a probability machine learning damage prediction model; (5) determining the unsafe probability of the building group; and (6) deducing a regional vulnerability model for the building group. Using simplified MDOF models based on building attribute parameters, numerical models accounting for variability between buildings are efficiently constructed. The probability machine learning model quantifies the intrinsic randomness of building responses and provides probability distribution parameters needed for the parameterized vulnerability model. From the unsafe probability of each building, the regional seismic vulnerability model is derived using Poisson binomial distribution.

### CROSS-REFERENCE TO RELATED APPLICATION

This application claims the priority benefit of China application serial no. 202411282024.0, filed on Sep. 13, 2024. The entirety of the above-mentioned patent application is hereby incorporated by reference herein and made a part of this specification.

### BACKGROUND OF THE INVENTION

### 1. Technical Field

The invention relates to the technical field of earthquake resistance of building structures, in particular to a method for analyzing the seismic vulnerability of an urban building group based on Poisson binomial distribution.

### 2. Description of Related Art

With the continuous urbanization in China, the urban population density and building density are becoming increasingly higher. Under the action of a strong earthquake, large-scale structural damage and dysfunctions of these urban buildings will be caused, and even the life safety and property safety of humans will be seriously threatened. So, it is necessary to carry out regional seismic vulnerability analysis of building groups, and this is also of great importance for urban disaster prevention and reduction. An urban area is generally formed by a great many of buildings, which may have different geometrical shapes and different material and structural characteristics, such as anti-lateral load systems and other details. The differences between urban buildings may bring a challenge to the development of vulnerability models of regional building groups. On one hand, a high calculation cost is needed for modeling of a large number of buildings in a region and performing nonlinear time history analysis (NLTHA), particularly when a detailed finite element model is used. To reduce the calculation cost of NLTHA, a simplified numerical model is needed to simulate nonlinear dynamic responses of buildings. On the other hand, existing study on the structural vulnerability of buildings is mainly orientated to a single building and cannot directly provide the number of unsafe buildings, which is particularly important for disaster reduction, in a region after an earthquake. Therefore, from the regional perspective, it is necessary to generate a seismic damage database of a building group by means of a simplified model to develop a regional seismic vulnerability model of the building group to depict the functional failure probability of the building group under different earthquake intensities, so as to realize extensible urban disaster resistance evaluation.

### BRIEF SUMMARY OF THE INVENTION

### Objective of the Invention

The objective of the invention is to provide a method for analyzing the seismic vulnerability of an urban building group based on Poisson binomial distribution, which constructs a seismic damage database of buildings by means of simplified models and constructs a regional seismic vulnerability model of a building group based on the seismic damage database.

### Technical Solution

The method for analyzing the seismic vulnerability of an urban building group based on Poisson binomial distribution according to the invention comprises the following steps:
S1: acquiring attribute parameters of a building group in a target city, and establishing a numerical model of each building;
S2: determining site features of the target city, and acquiring seismic motion records in conformity with the site features;
S3: performing nonlinear time history analysis on each building based on the seismic motion records and a numerical model of the building group, and constructing a seismic damage database of the building group in the target city;
S4: determining an optimal hyper-parameter based on an evaluation indicator, and establishing a probability machine learning model for predicting damage responses of the buildings;
S5: giving an earthquake scenario, and predicting, by means of the probability machine learning model, an unsafe probability of each building in the target city in the earthquake scenario; and
S6: based on Poisson binomial distribution, deducing a functional failure probability of the building group in the target city in the earthquake scenario according to the unsafe probability of each building, and repeatedly giving different earthquake scenarios to obtain a seismic vulnerability model of the building group in the target city;
further, in S1, eight attribute parameters of the building group are acquired, including a type of each building, an age of each building, the number of stories of each building, a total height of each building, the number of north-south spans of each building, the number of east-west spans of each building, a north-south spacing of each building, and an east-west spacing of each building;
further, in S1, the numerical model of each building is established by means of OpenSees software according to attribute parameters of each building;
wherein, a simplified multi-degree of freedom (MDOF) shear model is adopted for multi-story buildings, and a simplified MDOF bend-shear coupled model is adopted for high-rise buildings.

Further, in S2, the site features include a design intensity, a site condition and a seismic design group of the target city; the seismic motion records in conformity with the site features of the target city are acquired, and an intensity indicator AvgSA corresponding to each seismic motion record is calculated.

Further, in S3, the acquired seismic motion records are randomly input to the numerical model of each building to perform the nonlinear time history analysis to obtain engineering demand parameters (EDPs), such as the maximum inter-story drift ratio (MIDR) and the peak floor acceleration (PFA), of each building;
further, the seismic damage database constructed in S3 takes the earthquake intensity indicators and the attribute parameters of the buildings as inputs and takes the MIDR and the PFA as outputs.

Further, S4 comprises:
S41: randomly dividing the seismic damage database into a training set and a test set according to a proportion of P:Q, and using a natural gradient boosting decision tree NGBoost as a probability machine learning method;
S42: using a mean square error MSE as the evaluation indicator to determine the optimal hyper-parameter of the probability machine learning model, wherein MSE is calculated by the following formula:

$$MSE = \frac{1}{N} {\sum }_{i = 1}^{N} {( {y}_{i} - {\hat{y}}_{i} )}^{2}$$

wherein, y and ŷ are respectively a true value and a predicted value;
S43: representing prediction performance of the probability machine learning model by means of a goodness of fit R² and a root-mean-square error RMSE of the test set, wherein RMSE is calculated by the following formula:

$$RMSE = {( \frac{1}{N} {\sum }_{i = 1}^{N} {( {y}_{i} - {\hat{y}}_{i} )}^{2} )}^{1 / 2}$$

wherein, y and ŷ are respectively a true value and a predicted value.

Further, in S5, corresponding seismic motion intensity indicators and the attribute parameters of the buildings are input to the established probability machine learning model according to the given earthquake scenario to predict the unsafe probability P_{B,i} of each building in the target city in the earthquake scenario by the following formula:

$${P}_{i} = {P}_{i} ( {y}_{i} > {y}_{UO} \vert {x}_{IM} ) = 1 - Φ ( \frac{l n ( {y}_{UO} ) - {μ}_{l n y , i}}{{σ}_{l ny , i}} )$$

wherein, y_{OU} is a threshold corresponding to an unsafe state of the buildings, and when a building is seriously damaged, the building is considered as being in the unsafe state; ln(⋅) denotes a natural logarithm; Φ(⋅) denotes a standard normal cumulative distribution function CDF; μ_{lny,I} and σ_{lny,i} are respectively a mean and a standard deviation of responses of an i^{th} building and are provided by the probability machine learning model.

Further, S6 specifically comprises the following steps:
first, according to the unsafe probability Pᵢ (i=1, 2, . . . , N) of each building, determining the number z of unsafe buildings in the target city, which follows the following Poisson binomial distribution:

$$P ( z \vert {x}_{IM} ) = {\sum }_{A ∈ {F}_{z}} {\prod }_{i ∈ A} {P}_{i} {\prod }_{{iϵA}^{c}} ( 1 - {P}_{i} )$$

wherein, Pᵢ is the unsafe probability of an i^{th} building; Fz is defined as a set of all subsets with a value of z; Ac is a complementary set of a set A; according to a Poisson binomial distribution function, a mean μ and a variance σ² of the number z of unsafe buildings in the target city are calculated by the following formulas:

$$μ = {\sum }_{i = 1}^{N} {P}_{i}$$

$${σ}^{2} = {\sum }_{i = 1}^{N} {P}_{i} ( 1 - {P}_{i} )$$

then, representing the functional failure probability of the building group in the target city by a proportion of the number of unsafe buildings in the target city, and calculating an expectation of the functional failure probability of the building group by the following formula:

$$P ( z = μ \vert {x}_{IM} ) = μ / N = {\sum }_{i = 1}^{N} {P}_{i} / N$$

wherein, Pᵢ is the unsafe probability of the i^{th} building, and N is the number of all the buildings in the target city.

### Beneficial Effects

Compared with the prior art the invention has the following remarkable advantages: by means of the simplified MDOF models based on the attribute parameters of buildings, numerical models of the buildings, that take into account the variability between the buildings, can be constructed efficiently and quickly; the probability machine learning model can quantify the intrinsic randomicity of responses of the buildings and can directly provide probability distribution parameters required by the parameterized vulnerability model; different from traditional study which only focuses on the damage probability of a single building, the regional seismic vulnerability of a building group can be evaluated based on Poisson binomial distribution; the established vulnerability model of the building group comprises structural and non-structural component damage and can effectively support the evaluation of the loss, risk and tenacity of the urban building group.

### BRIEF DESCRIPTION OF THE SEVERAL VIEWS OF THE DRAWINGS

FIG. 1 is a flow diagram according to the invention;

FIG. 2 is a spectral acceleration diagram of seismic motion records according to the invention;

FIGS. 3A and 3B illustrate the prediction performance of a machine learning model according to the invention;

FIGS. 4A and 4B illustrate cloud charts of the unsafe probability of a building group according to the invention;

FIGS. 5A and 5B illustrate curves of the regional vulnerability of a building group according to the invention.

### DETAILED DESCRIPTION OF THE INVENTION

The technical solution of the invention is further described below in conjunction with the accompanying drawings.

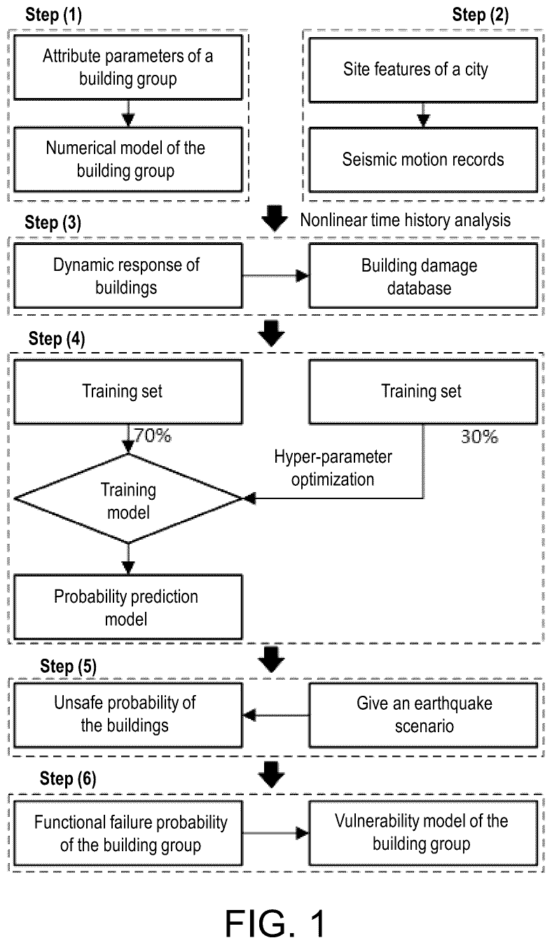

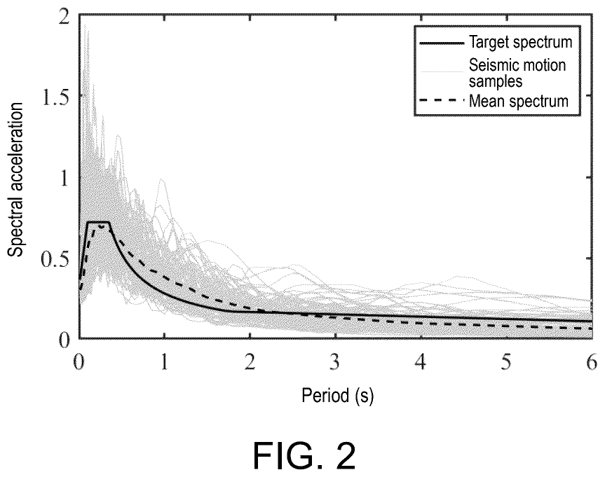

As shown in FIG. 1, one embodiment of the invention provides a method for analyzing the seismic vulnerability of an urban building group based on Poisson binomial distribution, comprising the following steps:
S1: attribute parameters of a building group in a target city are acquired, and a numerical model of each building is established. Specifically, eight attribute parameters of 1,000 buildings in the target city are collected, including the type of each building, the age of each building, the number of stories of each building, the total height of each building, the number of north-south spans of each building, the number of east-west spans of each building, the north-south spacing of each building and an east-west spacing of each building; according to attribute parameters of each building, and in OpenSees software, a simplified multi-degree of freedom (MDOF) shear model is used for establishing numerical models of multi-story buildings, and a simplified MDOF bend-shear coupled model is used for establishing numerical models of high-rise buildings.
S2: site features of the target city are determined, and seismic motion records in conformity with the site features are acquired. Specifically, according to the site features (a design intensity, a site condition and a seismic design group) of the target city, 100 seismic motion records in conformity with a target response spectrum are selected from an earthquake database of the pacific earthquake engineering research center, wherein the acceleration response spectrum and the mean response spectrum of the seismic motion records are shown in FIG. 2; the intensity indicator AvgSA corresponding to each seismic motion record is calculated.
S3: nonlinear time history analysis is performed on each building based on the seismic motion records and a numerical model of the building group to construct a seismic damage database of the building group in the target city. Specifically, the number of acquired seismic motion records is expanded from 100 1,000, the 1,000 seismic motion records are respectively and randomly input to the numerical models of the 1,000 buildings to perform nonlinear time history analysis to obtain the maximum inter-story drift ratio (MIDR) and the peak floor acceleration (PFA) of each building, wherein the constructed seismic damage database takes the earthquake intensity indicators and the attribute parameters of the buildings as inputs and takes the MIDR and the PFA as outputs.
S4: an optimal hyper-parameter is determined based on an evaluation indicator, and a probability machine learning model for predicting damage responses of the buildings is established. Specifically, the seismic damage database is randomly divided into a training set and a test set according to a proportion of 7:3, and a natural gradient boosting decision tree NGBoost is used for model training.

A mean square error MSE is used as the evaluation indicator to determine an optimal value of the hyper-parameter and obtain a probability machine learning prediction model, wherein the mean square error MSE is calculated by:

$$MSE = \frac{1}{N} {\sum }_{i = 1}^{N} {( {y}_{i} - {\hat{y}}_{i} )}^{2}$$

wherein, y and ŷ are respectively a true value and a predicted value;
Prediction performance of the probability machine learning model is represented by means of a goodness of fit R² and a root-mean-square error RMSE of the test set, wherein the RMSE is calculated by:

$$RMSE = {( \frac{1}{N} {\sum }_{i = 1}^{N} {( {y}_{i} - {\hat{y}}_{i} )}^{2} )}^{1 / 2}$$

wherein, y and ŷ are respectively a true value and a predicted value.

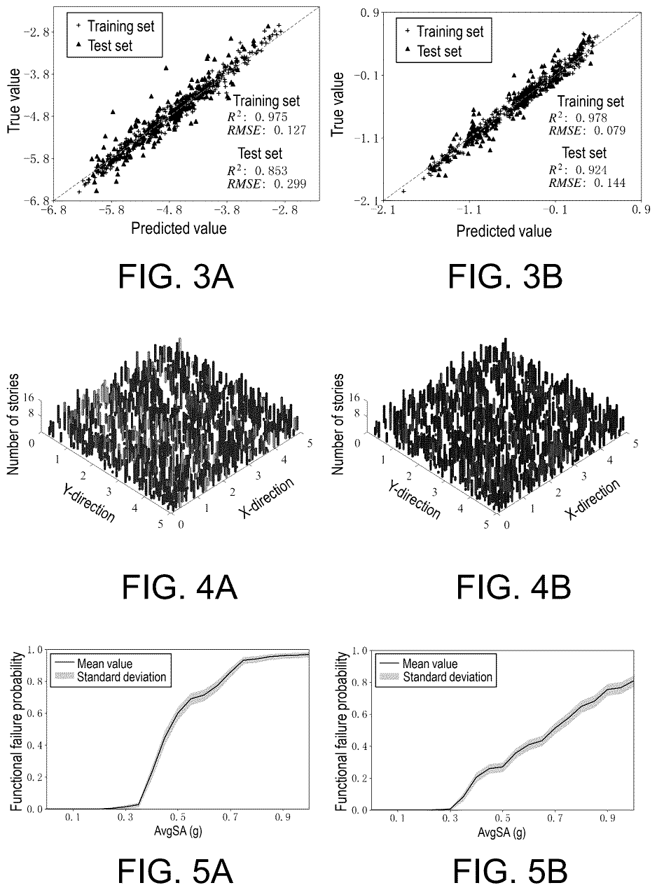

The mean prediction accuracy of the MIDR of the NGBoost model is shown by the test set and the training set. As shown in FIG. 3A, actual data points closely fit predicted data points along a line y=x, the RMSE is almost zero, and R² is 0.853. In addition, FIG. 3A shows the mean prediction accuracy of the PFA of the NGBoost model, wherein actual data points closely fit predicted data points, the RMSE of the training set and the RMSE of the test set are both close to 0, and R² is close to 1. The results indicate that the NGBoost model has high accuracy and can effectively predict damage responses of structural and non-structural components of buildings.
S5: an earthquake scenario is given, and an unsafe probability of each building in the target city in the earthquake scenario is predicted by means of the probability machine learning model. Specifically, the given earthquake scenario AvgSA=0.5 g and the attribute parameters of each building are input to the established probability machine learning model to predict the unsafe probability of each building in the target city in the earthquake scenario by the following formula:

$${P}_{i} = {P}_{i} ( {y}_{i} > {y}_{U O} \vert {x}_{IM} ) = 1 - Φ ( \frac{ln ( {y}_{UO} ) - {μ}_{lny , i}}{{σ}_{lny , i}} )$$

wherein, y_{OU} is a threshold corresponding to an unsafe state of the buildings; when a building is seriously damaged, the building is considered as being in the unsafe state; ln(⋅) denotes a natural logarithm; Φ(⋅) denotes a standard normal cumulative distribution function CDF; μ_{lny,I} and σ_{lny,i} are respectively a mean and a standard deviation of responses of an i^{th} building and are provided by the NGBoost model.

When it is determined that a building is seriously damaged according to a recommended damage state threshold, the building is unsafe: when the MIDR of structural components of a building is within 0.02-0.04, the building is unsafe; when the PFA of non-structural components of a building is within 0.40-0.80 g, the building is unsafe. In this way, the unsafe probability of structural components and the unsafe probability of non-structural components of each building in the target city in the given earthquake intensity AvgSA-0.5 g can be evaluated, which are respectively shown in FIG. 4A and FIG. 4B.
S6: based on Poisson binomial distribution, a functional failure probability of the building group in the target city in the earthquake scenario is deduced according to the unsafe probability of each building, and different earthquake scenarios are given repeatedly to obtain a seismic vulnerability model of the building group in the target city. Specifically:
first, according to the unsafe probability Pᵢ (i=1, 2, . . . , N) of each building, the number z of unsafe buildings in the target city, which follows the following Poisson binomial distribution, is determined:

$$P ( z \vert {x}_{IM} ) = {\sum }_{A ∈ {F}_{z}} {\prod }_{i ∈ A} {P}_{i} {\prod }_{{iϵA}^{c}} ( 1 - {P}_{i} )$$

wherein, Pᵢ is the unsafe probability of an i^{th} building; Fz is defined as a set of all subsets with a value of z; Ac is a complementary set of a set A; according to a Poisson binomial distribution function, a mean μ and a variance σ² of the number z of the unsafe buildings in the target city are calculated by the following formulas:

$$μ = {\sum }_{i = 1}^{N} {P}_{i}$$

$${σ}^{2} = {\sum }_{i = 1}^{N} {P}_{i} ( 1 - {P}_{i} )$$

then, the functional failure probability of the building group in the target city is represented by the proportion of the number of the unsafe buildings in the target city, and an expectation of the functional failure probability of the building group is calculated by the following formula:

$$P ( z = μ \vert {x}_{IM} ) = μ / N = {\sum }_{i = 1}^{N} {P}_{i} / N$$

wherein, Pᵢ is the unsafe probability of the i^{th} building, and N is the number of all the buildings in the target city.

FIG. 5A and FIG. 5B show the proportion of unsafe buildings under the action of different earthquake intensities, wherein FIG. 5A illustrates a vulnerability curve of structural damage of buildings based on the MIDR, and FIG. 5B illustrates a vulnerability curve of non-structural damage of buildings based on the FPA. Because the number of unsafe buildings is uncertain, the vulnerability curve of the building group in the target city is fluctuant, as shown by the dash area in FIG. 5A and FIG. 5B. As shown, the fluctuation of the regional seismic vulnerability of the building group is relatively small, indicating that the expectation of the proportion of unsafe buildings is acceptable.

What is claimed is:

1. A method for analyzing the seismic vulnerability of an urban building group based on Poisson binomial distribution, comprising the following steps:
S1: acquiring attribute parameters of a building group in a target city, and establishing a numerical model of each building;
S2: determining site features of the target city, and acquiring seismic motion records in conformity with the site features;
S3: performing nonlinear time history analysis on each building based on the seismic motion records and a numerical model of the building group, and constructing a seismic damage database of the building group in the target city;
S4: determining an optimal hyper-parameter based on an evaluation indicator, and establishing a probability machine learning model for predicting damage responses of the buildings;
S5: giving an earthquake scenario, and predicting, by means of the probability machine learning model, an unsafe probability of each building in the target city in the earthquake scenario; and
S6: based on Poisson binomial distribution, deducing a functional failure probability of the building group in the target city in the earthquake scenario according to the unsafe probability of each building, and repeatedly giving different earthquake scenarios to obtain a seismic vulnerability model of the building group in the target city;
wherein, in S1, the numerical model of each building is established by means of OpenSees software according to attribute parameters of each building;
wherein, a simplified multi-degree of freedom (MDOF) shear model is adopted for multi-story buildings, and a simplified MDOF bend-shear coupled model is adopted for high-rise buildings,
in S3, the acquired seismic motion records are randomly input to the numerical model of each building to perform the nonlinear time history analysis to obtain engineering demand parameters (EDPs) of each building,
the seismic damage database constructed in S3 takes the earthquake intensity indicators and the attribute parameters of the buildings as inputs and takes a maximum inter-story drift ratio (MIDR) and a peak floor acceleration (PFA) as outputs.

2. The method for analyzing the seismic vulnerability of an urban building group based on Poisson binomial distribution according to claim 1, wherein in S1, eight attribute parameters of the building group are acquired, including a type of each building, an age of each building, the number of stories of each building, a total height of each building, the number of north-south spans of each building, the number of east-west spans of each building, a north-south spacing of each building, and an east-west spacing of each building.

3. The method for analyzing the seismic vulnerability of an urban building group based on Poisson binomial distribution according to claim 1, wherein in S2, the site features are determined according to a design intensity, a site condition and a seismic design group of the target city; the seismic motion records in conformity with the site features of the target city are acquired, and an intensity indicator AvgSA corresponding to each seismic motion record is calculated.

4. The method for analyzing the seismic vulnerability of an urban building group based on Poisson binomial distribution according to claim 1, wherein S4 comprises:
S41: randomly dividing the seismic damage database into a training set and a test set according to a proportion of P:Q, and using a natural gradient boosting decision tree NGBoost as a probability machine learning method;
S42: using a mean square error MSE as the evaluation indicator to determine the optimal hyper-parameter of the probability machine learning model, wherein MSE is calculated by the following formula:
$$M S E = \frac{1}{N} {\sum }_{i = 1}^{N} {( {y}_{i} - {\hat{y}}_{i} )}^{2}$$
wherein, y and ŷ are respectively a true value and a predicted value;
S43: representing prediction performance of the probability machine learning model by means of a goodness of fit R² and a root-mean-square error RMSE of the test set, wherein RMSE is calculated by the following formula:
$$RMSE = {( \frac{1}{N} {\sum }_{i = 1}^{N} {( {y}_{i} - {\hat{y}}_{i} )}^{2} )}^{1 / 2}$$
wherein, y and ŷ are respectively a true value and a predicted value.

5. The method for analyzing the seismic vulnerability of an urban building group based on Poisson binomial distribution according to claim 1, wherein in S5, corresponding seismic motion intensity indicators and the attribute parameters of the buildings are input to the established probability machine learning model according to the given earthquake scenario to predict the unsafe probability Pᵢ of each building in the target city in the earthquake scenario by the following formula:
$${P}_{i} = {P}_{i} ( {y}_{i} > {y}_{UO} \vert {x}_{IM} ) = 1 - Φ ( \frac{ln ( {y}_{UO} ) - {μ}_{l n y , i}}{{σ}_{l ny , i}} )$$
wherein, y_{OU} is a threshold corresponding to an unsafe state of the buildings, and when a building is seriously damaged, the building is considered as being in the unsafe state; ln(⋅) denotes a natural logarithm; Φ(⋅) denotes a standard normal cumulative distribution function CDF; μ_{lny,I} and σ_{lny,i} are respectively a mean and a standard deviation of responses of an i^{th} building and are provided by the probability machine learning model.

6. The method for analyzing the seismic vulnerability of an urban building group based on Poisson binomial distribution according to claim 1, wherein S6 specifically comprises the following steps:
first, according to the unsafe probability Pᵢ (i=1, 2, . . . , N) of each building, determining the number z of unsafe buildings in the target city, which follows the following Poisson binomial distribution:
$$P ( z \vert {x}_{IM} ) = {\sum }_{A ∈ {F}_{z}} {\prod }_{i ∈ A} {P}_{i} {\prod }_{{iϵA}^{c}} ( 1 - {P}_{i} )$$
wherein, Pᵢ is the unsafe probability of an i^{th} building; Fz is defined as a set of all subsets with a value of z; Ac is a complementary set of a set A; according to a Poisson binomial distribution function, a mean μ and a variance σ² of the number z of unsafe buildings in the target city are calculated by the following formulas:
$$μ = {\sum }_{i = 1}^{N} {P}_{i}$$
$${σ}^{2} = {\sum }_{i = 1}^{N} {P}_{i} ( 1 - {P}_{i} )$$
then, representing the functional failure probability of the building group in the target city by a proportion of the number of unsafe buildings in the target city, and calculating an expectation of the functional failure probability of the building group by the following formula:
$$P ( z = μ \vert {x}_{IM} ) = μ / N = {\sum }_{i = 1}^{N} {P}_{i} / N$$
wherein, Pᵢ is the unsafe probability of the i^{th} building, and N is the number of all the buildings in the target city.
